(19) United States
(12) Patent Application Publication
(10) Pub. No.: US 2012/0106098 A1
(43) Pub. Date: May 3, 2012

(54) Flat Panel Display Apparatus and Method of Manufacturing the Same

(75) Inventors: Oh-Seob Kwon, Yongin-City (KR); Dong-Seop Park, Yongin-City (KR); Sung-Soo Koh, Yongin-City (KR); Jung-Jun Im, Yongin-City (KR); Byung-Uk Han, Yongin-City (KR); Jae-Sang Ro, Seoul (KR); Won-Eui Hong, Seoul (KR); Seog-Young Lee, Seoul (KR)

(73) Assignees: ENSIL TECH CO., LTD., Seoul (KR); SAMSUNG MOBILE DISPLAY CO., LTD., Yongin-City (KR)

(21) Appl. No.: 13/235,607

(22) Filed: Sep. 19, 2011

(30) Foreign Application Priority Data
Oct. 27, 2010 (KR) 10-2010-0105377

(51) Int. Cl. H05K 7/02; H01K 3/10

(52) U.S. Cl. 361/748; 29/850

(57) ABSTRACT

In a flat panel display apparatus having improved sealing and a method of manufacturing the same, the flat panel display apparatus comprises: a substrate; a display unit disposed on the substrate; a sealing substrate facing the display unit; a sealing member interposed between the substrate and the sealing substrate and surrounding the display unit; and a plurality of wiring groups comprising areas overlapping the sealing member between the substrate and the sealing substrate; wherein the wiring groups are disposed so as to surround the display unit, are spaced apart from an area corresponding to an edge of the display unit, and receive voltage from an external power source.

### CLAIM OF PRIORITY

This application makes reference to, incorporates the same herein, and claims all benefits accruing under 35 U.S.C. §119 from an application earlier filed in the Korean Intellectual Property Office on Oct. 27, 2010 and there duly assigned Serial No. 10-2010-0105377.

### BACKGROUND OF THE INVENTION

1. Field of the Invention

The present invention relates to a flat panel display apparatus and method of manufacturing the same, and more particularly, to a flat panel display apparatus having improved sealing characteristic and a method of manufacturing the same.

2. Description of the Related Art

Display devices are currently being replaced with portable and thin flat panel display apparatuses. In particular, flat panel display apparatuses, such as organic light emitting display apparatuses and liquid crystal display apparatuses, have recently been highlighted due to their excellent qualities.

In the flat panel display apparatus, a display unit is disposed on a substrate and a sealing substrate is disposed on the display unit to protect the display unit. Also, a sealing member is interposed between the substrate and the sealing substrate.

In the flat panel display apparatus, a sealing process is performed to protect the display unit from outside moisture, gas, and other foreign substances. According to a sealing characteristic, the quality of the flat panel display apparatus is significantly affected.

The sealing characteristic is dependent upon the sealing substrate and the sealing member. In particular, it is important that the sealing member be uniform.

However, a process of forming the sealing member is not easy, and thus there is a limit to improving the sealing characteristic.

### SUMMARY OF THE INVENTION

The present invention provides a flat panel display apparatus having improved sealing characteristic and a method of manufacturing the same.

According to an aspect of the present invention, there is provided a flat panel display apparatus including: a substrate; a display unit disposed on the substrate; a sealing substrate disposed facing the display unit; a sealing member interposed between the substrate and the sealing substrate so as to surround the display unit; and a plurality of wiring groups including areas overlapping the sealing member between the substrate and the sealing substrate; wherein the plurality of wiring groups are disposed to surround the display unit, are spaced apart from an area corresponding to the edge of the display unit, and receive voltage from an external power source.

The wiring groups each may include: a wiring unit overlapping the sealing member; connection units extending from both ends of the wiring unit; and inlet units each extending from one end of the connection unit and electrically connected to the external power source.

The connection units of the wiring groups which are adjacent to each other may be spaced apart from each other.

The sealing member may be disposed in a gap between the plurality of wiring groups which are adjacent to each other.

The gap may be a distance which is long enough to melt the sealing member disposed between the gaps by joule heat generated by the plurality of wiring groups as a result of applying a voltage thereto.

The plurality of wiring groups may include: a first wiring group spaced apart from the upper side of the display unit; a second wiring group be spaced apart from one side of the display unit; a third wiring group spaced apart from the lower side of the display unit; and a fourth wiring group spaced apart from the other side of the display unit.

The first wiring group may include a first wiring unit overlapping the sealing member, first connection units extending from both ends of the first wiring unit, and first inlet units extending from one end of the first connection unit and electrically connected to the external power source. The second wiring group includes a second wiring unit overlapping the sealing member, second connection units extending from both ends of the second wiring unit, and second inlet units extending from one end of the second connection unit and electrically connected to the external power source. The third wiring group includes a third wiring unit overlapping the sealing member, third connection units extending from both ends of the third wiring unit, and third inlet units extending from one end of the third connection unit and electrically connected to the external power source. The fourth wiring group includes a fourth wiring unit overlapping the sealing member, fourth connection units extending from both ends of the fourth wiring unit, and fourth inlet units extending from one end of the fourth connection unit and electrically connected to the external power source.

The first inlet unit and the second inlet unit, the second inlet unit and the third inlet unit, the third inlet unit and the fourth inlet unit, and the fourth inlet unit and the first inlet unit, each of which is adjacent to each other, may be spaced apart from each other by a predetermined interval.

The first inlet unit, the second inlet unit, the third inlet unit, and the fourth inlet unit are each exposed at one side of the substrate, and may be connected to the external power source.

The sealing member may include frit.

The wiring groups each may include a single wiring member.

The display unit may comprise an organic light-emitting device or a liquid crystal display device.

According to an aspect of the present invention, there is provided a method of manufacturing a flat panel display apparatus, the method including the steps of: preparing a substrate on which a display unit is disposed; disposing a sealing substrate facing the display unit; forming a sealing member between the substrate and the sealing substrate so as to surround the display unit; forming a plurality of wiring groups, including areas overlapping the sealing member between the substrate and the sealing substrate; and melting and hardening the sealing member by using heat generated by the wiring groups as a result of applying an external power source to the plurality of wiring groups; wherein the plurality of wiring groups which are adjacent to each other are spaced apart from each other by a predetermined interval and are electrically insulated from each other.

In the melting and hardening of the sealing member, the wiring groups which are not adjacent to each other may be selected from among the plurality of wiring groups, and the external power source may be applied to the selected wiring groups.

The wiring groups may each be disposed so as to correspond to a side of the display unit.

In the melting and hardening of the sealing member, the wiring groups which face each other may be selected from among the plurality of wiring groups, and the external power source may be applied to the selected wiring groups.

The wiring groups may be a first wiring group, a second wiring group, a third wiring group, and a fourth wiring group which are each spaced apart from four sides of the display unit.

The first wiring group may include a first wiring unit overlapping the sealing member, first connection units extending from both ends of the first wiring unit, and first inlet units extending from one end of the first connection unit and electrically connected to the external power source. The second wiring group includes a second wiring unit overlapping the sealing member, second connection units extending from both ends of the second wiring unit, and second inlet units extending from one end of the second connection unit and electrically connected to the external power source. The third wiring group includes a third wiring unit overlapping the sealing member, third connection units extending from both ends of the third wiring unit, and third inlet units extending from one end of the third connection unit and electrically connected to the external power source. The fourth wiring group includes a fourth wiring unit overlapping the sealing member, fourth connection units extending from both ends of the fourth wiring unit, and fourth inlet units extending from one end of the fourth connection unit and electrically connected to the external power source.

In the melting and hardening of the sealing member, the external power source may be applied by selecting the first inlet unit, the external power source may be applied by selecting the second inlet unit, the external power source may be applied by selecting the third inlet unit, and the external power source may be applied by selecting the fourth inlet unit.

In the melting and hardening of the sealing member, the first inlet unit and the third inlet unit which face each other may be selected and the external power source may be applied to each of the first inlet unit and the third inlet unit, and the second inlet unit and the fourth inlet unit which face each other may be selected and the external power source may be applied to each of the second inlet unit and the fourth inlet unit.

The sealing member may include frit.

The wiring groups may each include a single wiring member.

The display unit may comprise an organic light-emitting device or a liquid crystal display device.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a plan view schematically illustrating a flat panel display apparatus according to an embodiment of the present invention;

FIG. 2 is a cross-sectional diagram of the flat panel display apparatus of FIG. 1 cut along a line II-II of FIG. 1;

FIG. 3 is an expanded view of portion X of FIG. 1;

FIGS. 4A and 4B are plan views schematically illustrating the formation of a sealing member in a method of manufacturing the flat panel display apparatus of FIG. 1;

FIG. 5 is a plan view schematically illustrating a flat panel display apparatus according to another embodiment of the present invention; and

FIGS. 6A and 6B are plan views schematically illustrating the formation of a sealing member in a method of manufacturing the flat panel display apparatus of FIG. 5.

### DETAILED DESCRIPTION OF THE INVENTION

Hereinafter, one or more embodiments of the present invention will be described more fully with reference to the accompanying drawings.

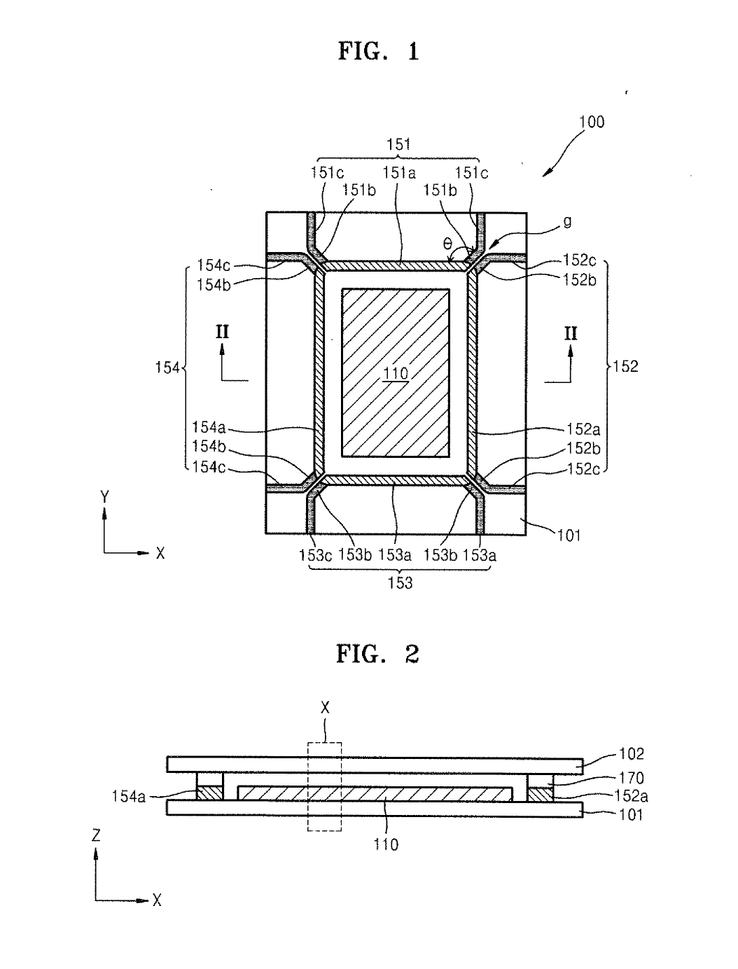

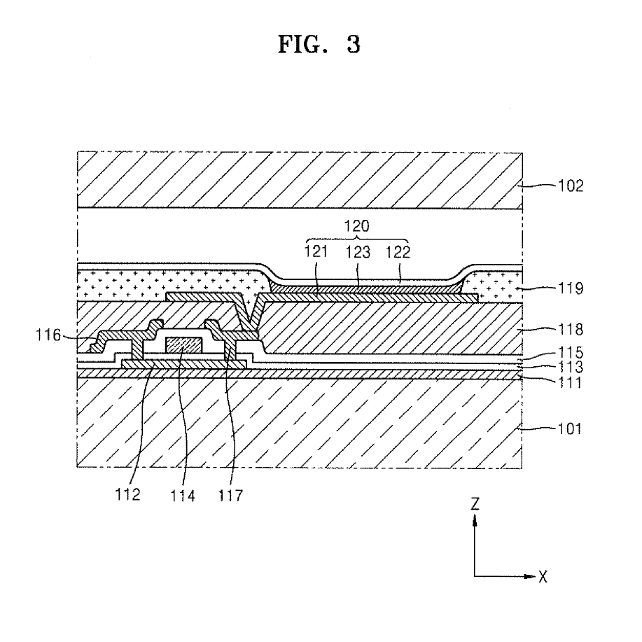

FIG. 1 is a plan view schematically illustrating a flat panel display apparatus according to an embodiment of the present invention, FIG. 2 is a cross-sectional diagram of the flat panel display apparatus of FIG. 1 cut along a line II-II of FIG. 1, and FIG. 3 is an expanded view of portion X of FIG. 2.

For convenience of description, a sealing substrate and a sealing member are not illustrated in FIG. 1, but sealing substrate 102 and sealing member 170 are illustrated in FIG. 2.

The flat panel display apparatus 100 may include a substrate 101, a display unit 110, a sealing substrate 102, first, second, third and fourth wiring groups 151, 152, 153 and 154, respectively, and sealing member 170.

The first wiring group 151 includes a first wiring unit 151a, first connection units 151b, and first inlet units 151c. The second wiring group 152 includes a second wiring unit 152a, second connection units 152b, and second inlet units 152c. The third wiring group 153 includes a third wiring unit 153a, third connection units 153b, and third inlet units 153c. The fourth wiring group 154 includes a fourth wiring unit 154a, fourth connection units 154b, and fourth inlet units 154c.

Elements of the flat panel display apparatus 100 will be described more fully with reference to FIGS. 1 thru 3.

The substrate 101 may be formed of a transparent glass material with SiO₂ as a main component. However, the substrate 101 is not limited thereto and may be formed of a transparent plastic material. The transparent plastic material used to form the substrate 101 may include an organic material selected from the group consisting of polyethersulphone (PES), insulating organic material, polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose tri acetate (CTA), and cellulose acetate propionate (CAP).

The display unit 110 is disposed on the substrate 101. The display unit 110 may have various forms. In the current embodiment of the present invention, the display unit 110 comprises an organic light-emitting device 120. However, the present invention is not limited thereto, and the display unit 110 may comprises a liquid crystal device.

The sealing substrate 102 is disposed facing the display unit 110. The sealing member 170 is interposed between the substrate 101 and the sealing substrate 102. The sealing member 170 surrounds the display unit 110, and facilitates a combination of the substrate 101 and the sealing substrate 102. The sealing member 170 may contain frit.

The first, second, third and fourth wiring groups 151, 152, 153 and 154, respectively, may be formed surrounding the display unit 110. The first, second, third and fourth wiring groups 151, 152, 153 and 154, respectively, may be spaced apart from each other and insulated from each other. The first wiring group 151 may be spaced apart from the upper side of the display unit 110, the second wiring group 152 may be spaced apart from one side of the display unit 110, the third wiring group 153 may be spaced apart from the lower side of the display unit 110, and the fourth wiring group 154 may be spaced apart from the other side of the display unit 110.

The first, second, third and fourth wiring groups 151, 152, 153 and 154, respectively, may be formed on the substrate 101, the sealing member 170 may be formed on the first, second, third and fourth wiring units 151a, 152a, 153a and 154a, respectively, and the sealing substrate 102 may be formed on the sealing member 170. That is, the first, second, third and fourth wiring units 151a, 152a, 153a and 154a, respectively, may overlap the sealing member 170.

More specifically, a material used to form the sealing member 170 is disposed on the first, second, third and fourth wiring units 151a, 152a, 153a and 154a, respectively, and then a voltage is applied to the first, second, third and fourth wiring groups 151, 152, 153 and 154, respectively, through an external power source (not shown). Thus, joule heat is generated by the first, second, third and fourth wiring groups 151, 152, 153 and 154, respectively, and the material used to form the sealing member 170 melts and hardens due to the heat, thereby forming the sealing member 170.

Widths of the first, second, third and fourth wiring units 151a, 152a, 153a and 154a, respectively, may each correspond to a width of the sealing member 170, or may be slightly smaller or larger than the width of the sealing member 170 according to the process conditions.

The first, second, third and fourth connection units 151b, 152b, 153b and 154b, respectively, may be formed at both ends of the first, second, third and fourth wiring units 151a, 152a, 153a and 154a, respectively.

The first connection units 151b extend from both ends of the first wiring unit 151a, respectively, and may bend away from the display unit 110 in a Y-direction. The second connection units 152b extend from both ends of the second wiring unit 152a, respectively, and may bend away from the display unit 110 in an X-direction. The third connection units 153b extend from both ends of the third wiring unit 153a, respectively, and may bend away from the display unit 110 in a −Y-direction. The fourth connection units 154b extend from both ends of the fourth wiring unit 154a, respectively, and may bend away from the display unit 110 in a −X-direction.

At corners of the flat panel display apparatus 100, The first connection unit 151b and the second connection unit 152b are spaced apart from each other, the second connection unit 152b and the third connection unit 153b are spaced apart from each other, the third connection unit 153b and the fourth connection unit 154b are spaced apart from each other, and the fourth connection unit 154b and the first connection unit 151b are spaced apart from each other.

The gaps g between the first connection unit 151b and the second connection unit 152b, the second connection unit 152b and the third connection unit 153b, the third connection unit 153b and the fourth connection unit 154b, and the fourth connection unit 154b and the first connection unit 151b at corners of the flat panel display apparatus 100 may be the same.

The first, second, third and fourth inlet units 151c, 152c, 153c and 154c, respectively, may extend from one end of the first, second, third and fourth connection units 151b, 152b, 153b and 154b, respectively. That is, the first, second, third and fourth inlet units 151c, 152c, 153c and 154c, respectively, may be connected to the first, second, third and fourth wiring units 151a, 152a, 153a and 154a, respectively, through the first, second, third and fourth connection units 151b, 152b, 153b and 154b, respectively.

The first inlet units 151c may each extend from one end of the first connection unit 151b, and may be exposed at one side of the substrate 101. As illustrated in FIG. 1, the first inlet units 151c may extend from the first connection unit 151b, and may bend in an upward direction (Y-direction) of the flat panel display apparatus 100.

The second inlet units 152c may each extend from one end of the second connection unit 152b, and may be exposed at one side of the substrate 101. As illustrated in FIG. 1, the second inlet units 152c may extend from the second connection unit 152b, and may bend in an X-direction of the flat panel display apparatus 100.

The third inlet units 153c may each extend from one end of the third connection unit 153b, and may be exposed at one side of the substrate 101. As illustrated in FIG. 1, the third inlet units 153c may extend from the third connection unit 153b, and may bend in a downward direction (Y-direction) of the flat panel display apparatus 100.

The fourth inlet units 154c may each extend from one end of the fourth connection unit 154b, and may be exposed at one side of the substrate 101. As illustrated in FIG. 1, the fourth inlet units 154c may extend from the fourth connection unit 154b, and may bend in an X-direction of the flat panel display apparatus 100.

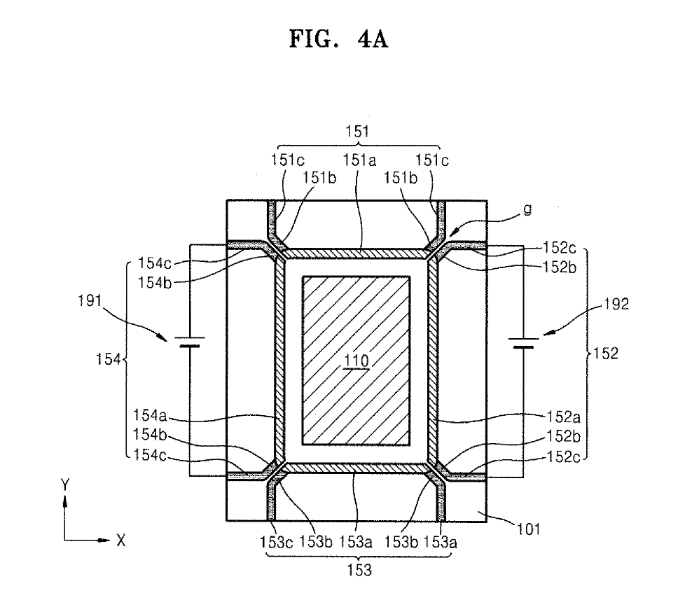

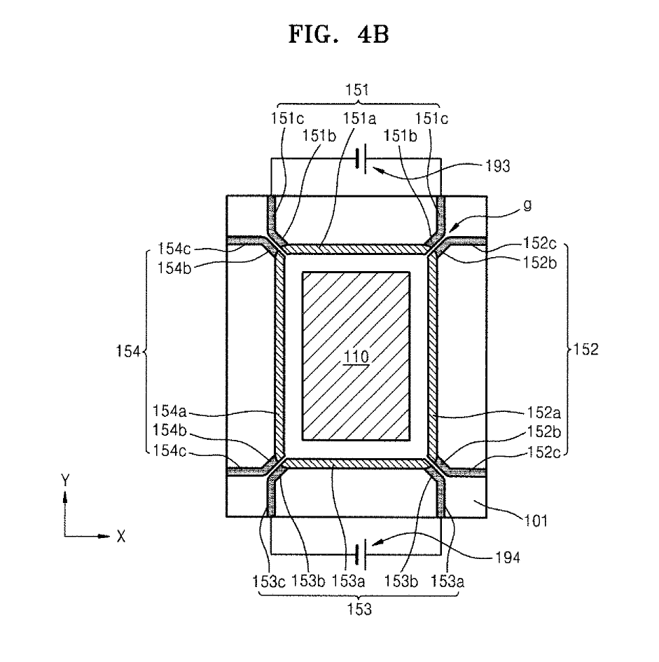

In the forming of the sealing member 170, at least one of the first, second, third and fourth inlet units 151c, 152c, 153c and 154c, respectively, is selected, and voltage may be applied to the selected inlet units through the external power source. For example, voltage may be applied by selecting one of the first, second, third and fourth inlet units 151c, 152c, 153c and 154c, respectively, and then voltage may be applied by selecting the other inlet units. Also, voltage may be applied by selecting the inlet units of the wiring units which face each other. That is, the first inlet units 151c and the third inlet units 153c of the first wiring group 151 and the third wiring group 153, respectively, which face each other, are selected and power is applied thereto. Then, the second inlet units 152c and the fourth inlet units 154c of the second wiring group 152 and the fourth wiring group 154, respectively, which face each other, are selected and power is applied thereto. Also, voltage may be simultaneously applied to the first, second, third and fourth inlet units 151c, 152c, 153c and 154c, respectively. Accordingly, defects generated at corner areas may be prevented, which will be described more fully below with reference to FIGS. 4A and 4B.

The first, second, third and fourth inlet units 151c, 152c, 153c and 154c, respectively, are formed close to the sides of the substrate 101 so as to be easily connected electrically to the external power source.

The first, second, third and fourth inlet units 151c, 152c, 153c and 154c, respectively, may be each formed of a conductive material, which may be the same as those of the wiring units and connection units.

The display unit 110 according to the present invention may have various forms. In the current embodiment of the present invention, the display unit 110 may comprise the organic light-emitting device 120, as will be described more fully below with reference to FIG. 3.

A buffer layer 111 is formed on the substrate 101. The buffer layer 111 provides a planarized surface of the substrate 101, and prevents moisture and foreign substances from penetrating into the substrate 101.

An active layer 112 having a predetermined pattern is formed on the buffer layer 111. The active layer 112 may be formed of an inorganic semiconductor or an organic semiconductor, such as amorphous silicon or polysilicon, and may include source, drain and channel areas.

The source and drain areas may be formed by doping the active layer 112, formed of amorphous silicon or polysilicon, with impurities.

When the active layer 112 is doped with boron (B), a group III element, a p-type semiconductor may be formed. When the active layer 112 is doped with nitrogen, a group V element, an n-type semiconductor may be formed.

A gate insulation layer 113 (FIG. 3) is formed on the active layer 112, and a gate electrode 114 is formed on a predetermined area of the gate insulation layer 113. The gate insulation layer 113 insulates the active layer 112 from the gate electrode 114, and may include an organic material or an inorganic material, such as SiNx or SiO₂.

The gate electrode 114 may include a metal, such as Au, Ag, Cu, Ni, Pt, Pd, Al, Mo, or an alloy, such as Al:Nd or Mo: W, or alloys thereof. However, the present invention is not limited thereto, and the gate electrode 114 may include various materials in consideration of adhesion properties, planarization, electric resistance, and processability. The gate electrode 114 is connected to a gate line (not illustrated) by means of which an electric signal is applied thereto.

An interlayer insulation layer 115 is formed on the gate electrode 114. The interlayer insulation layer 115 and the gate insulation layer 113 are formed so as to expose the source and drain areas of the active layer 112. A source electrode 116 and a drain electrode 117 are connected to the exposed source and drain areas of the active layer 112.

Materials used to form the source electrode 116 and the drain electrode 117 may include not only Au, Pd, Pt, Ni, Rh, Ru, Ir, or Os but also alloys including at least two metals such as Al, Mo, an Al:Nd alloy, or a MoW alloy. However, the present invention is not limited thereto.

A passivation layer 118 is formed to cover the source electrode 116 and the drain electrode 117. The passivation layer 118 may include an inorganic insulation layer and/or an organic insulation layer. As the inorganic insulation layer, the passivation layer 118 may include SiO₂, SiNₓ, SiON, Al₂ O₃, TiO₂, Ta₂ O₅, HfO₂, ZrO₂, BST, or PZT. As the organic insulation layer, the passivation layer 118 may include a general common polymer such as PMMA or PS, a polymer derivative having a phenol group, an acryl-based polymer, an imide-based polymer, an aryl ether-based polymer, an amide-based polymer, a fluorinated polymer, a p-xylene based polymer, a vinyl alcohol-based polymer, or blends thereof. The passivation layer 118 may include a complex stack structure of an inorganic insulation layer and an organic insulation layer.

The passivation layer 118 is formed so as to expose the drain electrode 117, and the organic light-emitting device 120 is formed so as to connect to the exposed drain electrode 117.

The organic light-emitting device 120 includes a first electrode 121, a second electrode 122, and an intermediate layer 123. More specifically, the first electrode 121 contacts the drain electrode 117.

The intermediate layer 123 includes an organic emission layer. When voltage is applied through the first electrode 121 and the second electrode 122, visible rays are produced.

A pixel defining layer 119 is formed on the first electrode 121 by using an insulation material. A predetermined opening is formed in the pixel defining layer 119 so as to expose the first electrode 121. The intermediate layer 123 is formed on the exposed first electrode 121. Then, the second electrode 122 is formed so as to connect to the intermediate layer 123.

The first electrode 121 and the second electrode 122 may have the polarities of an anode and a cathode, respectively. Also, the first electrode 121 and the second electrode 122 may have the polarities of a cathode and an anode, respectively

The sealing substrate 102 is disposed on the second electrode 122.

FIGS. 4A and 4B are plan views schematically illustrating the formation of a sealing member in a method of manufacturing the flat panel display apparatus of FIG. 1. More specifically, FIGS. 4A and 4B illustrate the application of a voltage from an external power source in order to form the sealing member 170.

The method of manufacturing the flat panel display apparatus 100 of FIG. 1 includes various processes, including the forming of the sealing member 170. The forming of the sealing member 170 includes disposing a material used to form the sealing member 170 and applying voltage to the first, second, third and fourth wiring groups 151, 152, 153 and 154, respectively, in order to melt and harden the material.

Voltage may be applied to the first, second, third and fourth wiring groups 151, 152, 153 and 154, respectively, by selecting the wiring groups which are not adjacent to each other at the corner areas and face each other.

More specifically, referring to FIG. 4A, the fourth wiring group 154 and the second wiring group 152 are not adjacent to each other at the corner areas and face each other on the display unit 110. Thus, the fourth wiring group 154 and the second wiring group 152 are selected for application of an external power source. That is, both terminals of an external power source 191 may be connected to the fourth inlet units 154c of the fourth wiring group 154, and both terminals of a power source 192 may be connected to the second inlet units 152c of the second wiring group 152, respectively. Then, when voltage is applied, joule heat is generated by the fourth wiring unit 154a and the second wiring unit 152a. Accordingly, the material used to form the sealing member 170, which is disposed so as to overlap the fourth wiring unit 154a and the second wiring unit 152a, may easily melt and harden.

Referring to FIG. 4B, an external power source may be applied to the first wiring group 151 and the third wiring group 153, which are not adjacent to each other at the corner areas, and which are disposed facing each other on the display unit 110. That is, both terminals of an external power source 193 may be connected to the first inlet units 151c of the first wiring group 151, and both terminals of an external power source 194 may be connected to the third inlet units 153c of the third wiring group 153. Then, when voltage is applied, joule heat is generated by the first wiring unit 151a and the third wiring unit 153a. Accordingly, the material used to form the sealing member 170, which is disposed so as to overlap the first wiring unit 151a and the third wiring unit 153a may easily melt and harden.

In FIGS. 4A and 4B, a power source is applied to the fourth wiring group 154 and the second wiring group 152, and then a power source is applied to the first wiring group 151 and the third wiring group 153. However, the present invention is not limited thereto. A power source may be applied to the first wiring group 151 and the third wiring group 153, and then a power source may be applied to the fourth wiring group 154 and the second wiring group 152. Also, a power source may be simultaneously applied to the first, second, third and fourth wiring groups 151, 152, 153 and 154, respectively.

The first connection unit 151b and the second connection unit 152b, the other second connection unit 152b and the third connection unit 153b, the other third connection unit 153b and the fourth connection unit 154b, and the other fourth connection unit 154b and the other first connection unit 151b are each spaced apart from each other by a predetermined gap g. However, the sealing member 170 is disposed between each gap g. Thus, when a power source is applied, joule heat may be transferred to the sealing member 170 from the first, second, third and fourth wiring units 151a, 152a, 153a and 154a, respectively, and thus the sealing member 170 disposed between each gap g may melt. Accordingly, the gaps g between the first, second, third and fourth connection units 151b, 152b, 153b and 154b, respectively, may be a distance that is long enough to melt the sealing member 170 disposed in the gap g by the joule heat transferred from the first, second, third and fourth wiring units 151a, 152a, 153a and 154a, respectively.

According to the embodiment of the present invention, since the first, second, third and fourth wiring groups 151, 152, 153 and 154, respectively, are spaced apart from each other by the predetermined gap g, the joule heat may be prevented from being centralized at the corner areas when applying a power source, and sealing defects at the corner area due to centralization of heat at the corner area may be improved.

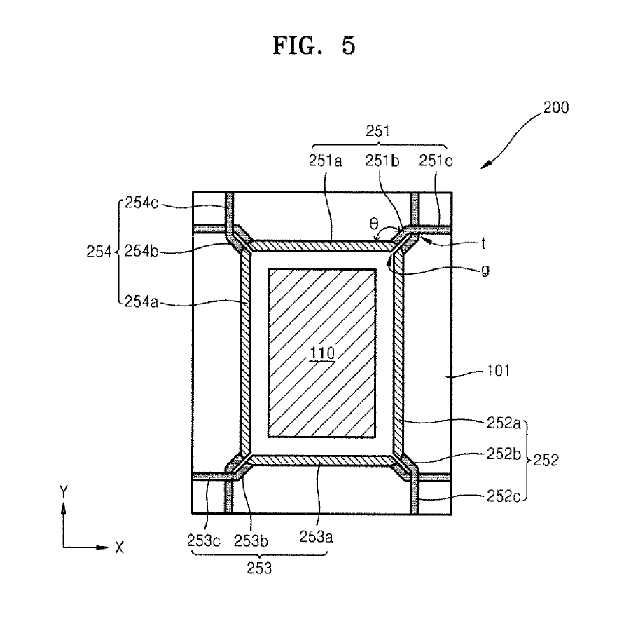

FIG. 5 is a plan view schematically illustrating a flat panel display apparatus according to another embodiment of the present invention. For convenience of description, the sealing substrate 102 and the sealing member 170 are not illustrated in FIG. 5, and only differences from the flat panel display apparatus 100 of FIG. 1 will be described.

The flat panel display apparatus 200 may include the substrate 101, the display unit 110, the sealing substrate 102, first, second, third and fourth wiring groups 251, 252, 253 and 254, respectively, and the sealing member 170.

The first wiring group 251 includes a first wiring unit 251a, first connection units 251b, and first inlet units 251c. The second wiring group 252 includes a second wiring unit 252a, second connection units 252b, and second inlet units 252c. The third wiring group 253 includes a third wiring unit 253a, third connection units 253b, and third inlet units 253c. The fourth wiring group 254 includes a fourth wiring unit 154a, fourth connection units 254b, and fourth inlet units 254c.

Elements of the flat panel display apparatus 200 will be described more fully with reference to FIG. 5.

The display unit 110 is formed on the substrate 101. The sealing substrate (not illustrated) is disposed facing the display unit 110. The sealing member (not illustrated) is interposed between the substrate 101 and the sealing substrate (not illustrated). The sealing member (not illustrated) is formed so as to surround the display unit 110. The sealing member (not illustrated) facilitates a combination of the substrate 101 and the sealing substrate (not illustrated). The sealing member (not illustrated) may contain frit.

The first, second, third and fourth wiring groups 251, 252, 253 and 254, respectively, may be formed on the substrate 101 so as to surround the display unit 110. In particular, the sealing member 170 (see FIG. 2) may be formed on the first, second, third and fourth wiring units 251a, 252a, 253a and 254a, respectively, of the first, second, third and fourth wiring groups 251, 252, 253 and 254, respectively, and the sealing substrate 102 may be formed on the sealing member 170 (see FIG. 2). That is, the first, second, third and fourth wiring units 251a, 252a, 253a and 254a, respectively, may overlap the sealing member 170.

More specifically, a material used to form the sealing member 170 is disposed, and then voltage is applied to the first, second, third and fourth wiring groups 251, 252, 253 and 254, respectively, through an external power source. Thus, joule heat is generated by the first, second, third and fourth wiring groups 251, 252, 253 and 254, respectively, and the material used to form the sealing member 170 melts and hardens due to the heat, thereby finally forming the sealing member 170.

Widths of the first, second, third and fourth wiring units 251a, 252a, 253a and 254a, respectively, may each correspond to a width of the sealing member 170, or may be slightly smaller or larger than the width of the sealing member 170 according to the process conditions.

The first, second, third and fourth connection units 251b, 252b, 253b and 254b, respectively, may be formed at both ends of the first, second, third and fourth wiring units 251a, 252a, 253a and 254a, respectively.

The first connection units 251b extend from both ends of the first wiring unit 251a, respectively, and may bend away from the display unit 110 in a Y-direction. The second connection units 252b extend from both ends of the second wiring unit 252a, respectively, and may bend away from the display unit 110 in an X-direction. The third connection units 253b extend from both ends of the third wiring unit 253a, respectively, and may bend away from the display unit 110 in a Y-direction. The fourth connection units 254b extend from both ends of the fourth wiring unit 254a, respectively, and may bend away from the display unit 110 in an X-direction.

At corners of the flat panel display apparatus 200, The first connection unit 251b and the second connection unit 252b are spaced apart from each other, the second connection unit 252b and the third connection unit 253b are spaced apart from each other, the third connection unit 253b and the fourth connection unit 254b are spaced apart from each other, and the fourth connection unit 254b and the first connection unit 251b are spaced apart from each other.

The gaps g between the first connection unit 251b and the second connection unit 252b, between the second connection unit 252b and the third connection unit 253b, between the third connection unit 253b and the fourth connection unit 254b, and between the fourth connection unit 254b and the first connection unit 251b at corners of the flat panel display apparatus 200 may be the same.

The first, second, third and fourth inlet units 251c, 252c, 253c and 254c, respectively, may extend from one end of the first, second, third and fourth connection units 251b, 252b, 253b and 254b, respectively. That is, the first, second, third and fourth inlet units 251c, 252c, 253c and 254c, respectively, may be connected to the first, second, third and fourth wiring units 251a, 252a, 253a and 254a, respectively, through the first, second, third and fourth connection units 251b, 252b, 253b and 254b, respectively.

The first inlet units 251c may each extend from one end of the first connection unit 251b and be exposed at sides of the substrate 101. As illustrated in FIG. 5, the first inlet units 251c may extend from the first connection unit 251b, and may bend in directions (X and −X directions) of the flat panel display apparatus 200.

The second inlet units 252c may each extend from one end of the second connection unit 252b and be exposed at sides of the substrate 101. As illustrated in FIG. 5, the second inlet units 252c may extend from the second connection unit 252b and may bend in upward and downward directions (Y and −Y directions, respectively) of the flat panel display apparatus 200.

The third inlet units 253c may each extend from one end of the third connection unit 253b and may be exposed at sides of the substrate 101. As illustrated in FIG. 5, the third inlet units 253c may extend from the third connection unit 253b and may bend in directions (X and −X direction) of the flat panel display apparatus 200.

The fourth inlet units 254c may each extend from one end of the fourth connection unit 254b and may be exposed at sides of the substrate 101. As illustrated in FIG. 5, the fourth inlet units 254c may extend from the fourth connection unit 254b and may bend in upward and downward directions (Y and −Y directions) of the flat panel display apparatus 200.

In FIG. 5, the first, second, third and fourth inlet units 251c, 252c, 253c and 254c, respectively, are formed as described above. Thus, the first inlet unit 251c and the second inlet unit 252c cross each other at corners of the flat panel display apparatus 200. The second inlet unit 252c and the third inlet unit 253c cross each other at corners of the flat panel display apparatus 200. The third inlet unit 253c and the fourth inlet unit 254c cross each other at corners of the flat panel display apparatus 200. The fourth inlet unit 254c and the first inlet unit 251c cross each other at corners of the flat panel display apparatus 200.

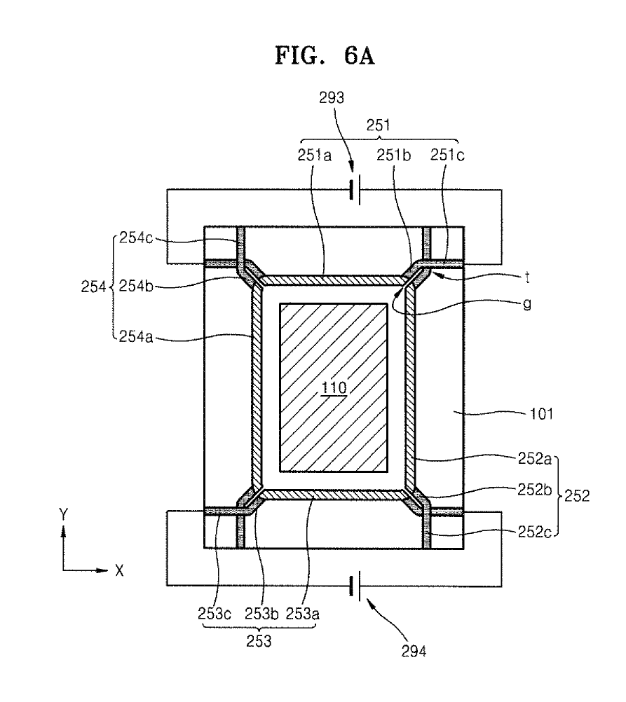

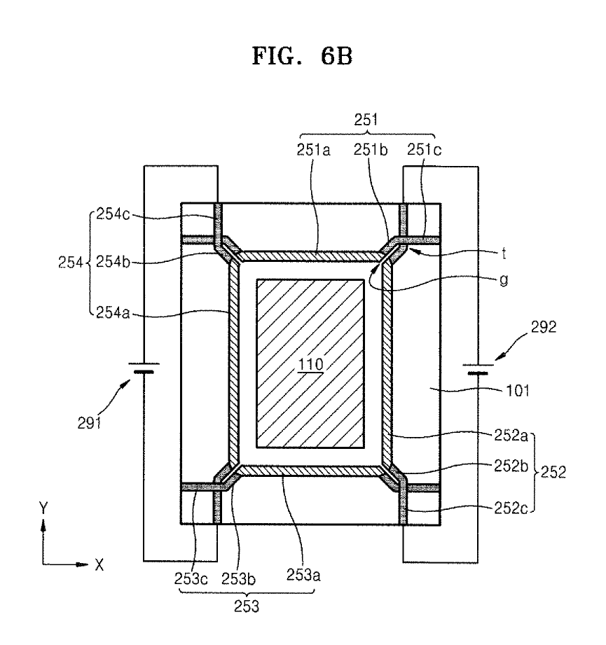

In the forming of the sealing member 170, one of the first, second, third and fourth inlet units 251c, 252c, 253c and 254c, respectively, is selected, and voltage may be applied to the selected inlet unit from an external power source, which will be described more fully with reference to FIGS. 6A and 6B.

The first, second, third and fourth inlet units 251c, 252c, 253c and 254c, respectively, are formed close to the sides of the substrate 101 so as to be easily electrically connected to an external power source (not illustrated).

The first, second, third and fourth inlet units 251c, 252c, 253c and 254c, respectively, may be each formed of a conductive material, which may be the same as those of the wiring units and connection units.

FIGS. 6A and 6B are plan views schematically illustrating the formation of a sealing member in a method of manufacturing the flat panel display apparatus of FIG. 5. More specifically, FIGS. 6A and 6B illustrate the application of voltage from an external power source in order to form the sealing member 170.

A method of manufacturing the flat panel display apparatus 200 of FIG. 5 comprises various processes including forming the sealing member 170. The forming of the sealing member 170 includes disposing a material used to form the sealing member 170 and applying voltage to the first, second, third and fourth wiring groups 251, 252, 253 and 254, respectively, in order to melt and harden the material.

Voltage may be sequentially applied to the first, second, third and fourth wiring groups 251, 252, 253 and 254, respectively.

More specifically, referring to FIG. 6A, the first wiring group 251 is initially selected and a first external power source 293 is applied thereto. That is, both terminals of the first external power source 293 may be connected to the first inlet units 251c of the first wiring group 251. Then, when voltage is applied, joule heat is generated not only by the first wiring unit 251a but also by second, third and fourth wiring units 252a, 253a and 254a, respectively. This is because the first inlet unit 251c and the second inlet unit 252c cross each other, the second inlet unit 252c and the third inlet unit 253c cross each other, the third inlet unit 253c and the fourth inlet unit 254c cross each other, and the fourth inlet unit 254c and the first inlet unit 251c cross each other.

The first external power source 293 applies voltage so that the sealing member 170, overlapping the first wiring unit 251a, may melt only due to the joule heat generated by the first wiring unit 251a. That is, since the first inlet unit 251c and the second inlet unit 252c, the second inlet unit 252c and the third inlet unit 253c, third inlet unit 253c and the fourth inlet unit 254c, and the fourth inlet unit 254c and the first inlet unit 251c cross each other, a current flows in the first, second, third and fourth wiring units 251a, 252a, 253a and 254a, respectively, even if voltage is only applied to the first inlet unit 251c. However, the first wiring unit 251a is connected in parallel with the second, third and fourth wiring units 252a, 253a and 254a, respectively, wherein the second, third and fourth wiring units 252a, 253a and 254a, respectively, are each connected in series. Thus, an amount of current flowing in the first wiring unit 251a is larger than an amount of current flowing in the second, third and fourth wiring units 252a, 253a and 254a, respectively. Accordingly, joule heat generated by the first wiring unit 251a is greater than joule heat each generated by the second, third and fourth wiring units 252a, 253a and 254a, respectively. Thus, the sealing member 170 overlapping the first wiring unit 251a may melt according to the amount of voltage from the first external power source 293, whereas the sealing member 170 overlapping the second, third and fourth wiring units 252a, 253a and 254a, respectively, may not be melted. In the present invention, the first external power source 293, by which the sealing member 170 overlapping the first wiring unit 251a is melted, and the sealing member 170 overlapping the second, third and fourth wiring units 252a, 253a and 254a, respectively, is melted, is applied to the first inlet unit 251c.

Then, the third wiring group 253 is selected and a second external power source 294 is applied thereto. That is, both terminals of the second external power source 294 may be connected to the third inlet units 253c of the third wiring group 251. Then, when voltage is applied, joule heat is generated not only by the third wiring unit 253a but also by the first, second and fourth wiring units 251a, 252a and 254a, respectively. This is because the first inlet unit 251c and the second inlet unit 252c cross each other, the second inlet unit 252c and the third inlet unit 253c cross each other, the third inlet unit 253c and the fourth inlet unit 254c cross each other, and the fourth inlet unit 254c and the first inlet unit 251c cross each other.

The second external power source 294 applies voltage so that the sealing member 170, overlapping the third wiring unit 253a, may melt only due to the joule heat generated by the third wiring unit 253a.

Then, referring to FIG. 6B, the second wiring group 252 is selected, and a third external power source 292 is applied thereto. That is, both terminals of the third external power source 292 may be connected to the second inlet units 252c of the second wiring group 252. Then, when voltage is applied, joule heat is generated not only by the second wiring unit 252a but also by first, third and fourth wiring units 251a, 253a and 254a, respectively. This is because the first inlet unit 251c and the second inlet unit 252c cross each other, the second inlet unit 252c and the third inlet unit 253c cross each other, the third inlet unit 253c and the fourth inlet unit 254c cross each other, and the fourth inlet unit 254c and the first inlet unit 251c cross each other.

The third external power source 292 applies voltage so that the sealing member 170 overlapping the second wiring unit 252a, may melt only due to the joule heat generated by the second wiring unit 252a.

Then, the fourth wiring group 254 is selected, and a fourth external power source 291 is applied thereto. That is, both terminals of the fourth external power source 291 may be connected to the fourth inlet units 254c of the fourth wiring group 254. Then, when voltage is applied, joule heat is generated not only by the fourth wiring unit 254a but also by the first, second and third wiring units 251a, 252a and 253a, respectively. This is because the first inlet unit 251c and the second inlet unit 252c cross each other, the second inlet unit 252c and the third inlet unit 253c cross each other, the third inlet unit 253c and the fourth inlet unit 254c cross each other, and the fourth inlet unit 254c and the first inlet unit 251c cross each other.

The fourth external power source 291 applies voltage so that the sealing member 170, overlapping the fourth wiring unit 254a, may melt only due to the joule heat generated by the fourth wiring unit 254a.

The first connection unit 251b and the second connection unit 252b, the second connection unit 252b and the third connection unit 253b, the third connection unit 253b and the fourth connection unit 254b, and the fourth connection unit 254b and the first connection unit 251b are each spaced apart from each other by a predetermined gap g. However, the sealing member 170 is disposed between each gap g. Thus, when a power source is applied, joule heat may be transferred to the sealing member 170 from the first, second, third and fourth wiring units 251a, 252a, 253a and 254a, respectively, and thus the sealing member 170 disposed between each gap g may melt. Accordingly, the gaps g between the first, second, third and fourth connection units 251b, 252b, 253b and 254b, respectively, may be a distance which is long enough to melt the sealing member 170 disposed in the gap g by the joule heat transferred from the first, second, third and fourth wiring units 251a, 252a, 253a and 254a, respectively.

According to the embodiment of the present invention, since the first, second, third and fourth wiring groups 251, 252, 253 and 254, respectively, are spaced apart from each other by the predetermined gap g, the joule heat may be prevented from being centralized at the corner areas when applying a power source, and sealing defects at the corner area due to centralization of heat at the corner area may be improved.

According to one or more embodiments of the present invention, the sealing characteristic of the flat panel display apparatus may be improved.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A flat panel display apparatus, comprising:
a substrate;
a display unit disposed on the substrate;
a sealing substrate facing the display unit;
a sealing member interposed between the substrate and the sealing substrate and surrounding the display unit; and
a plurality of wiring groups comprising areas overlapping the sealing member between the substrate and the sealing substrate;
wherein the wiring groups are disposed so as to surround the display unit, are spaced apart from an area corresponding to an edge of the display unit, and receive voltage from an external power source.

2. The flat panel display apparatus of claim 1, wherein the wiring groups each comprise:
a wiring unit overlapping the sealing member;
connection units extending from both ends of the wiring unit; and
inlet units, each extending from one end of the connection unit, and each electrically connected to the external power source.

3. The flat panel display apparatus of claim 2, wherein the connection units of wiring groups which are adjacent to each other are spaced apart from each other.

4. The flat panel display apparatus of claim 1, wherein the sealing member is disposed in a gap between wiring groups which are adjacent to each other.

5. The flat panel display apparatus of claim 4, wherein the gap is long enough to melt the sealing member disposed between the gaps by joule heat generated by the wiring groups as a result of the voltage received from the external power source.

6. The flat panel display apparatus of claim 1, wherein wiring groups include:
a first wiring group spaced apart from an upper side of the display unit;
a second wiring group spaced apart from one side of the display unit;
a third wiring group spaced apart from a lower side of the display unit; and
a fourth wiring group spaced apart from another side of the display unit.

7. The flat panel display apparatus of claim 6, wherein the first wiring group comprises a first wiring unit overlapping the sealing member, first connection units extending from both ends of the first wiring unit, and first inlet units extending from one end of the first connection unit and electrically connected to the external power source;
wherein the second wiring group comprises a second wiring unit overlapping the sealing member, second connection units extending from both ends of the second wiring unit, and second inlet units extending from one end of the second connection unit and electrically connected to the external power source;
wherein the third wiring group comprises a third wiring unit overlapping the sealing member, third connection units extending from both ends of the third wiring unit, and third inlet units extending from one end of the third connection unit and electrically connected to the external power source; and
wherein the fourth wiring group comprises a fourth wiring unit overlapping the sealing member, fourth connection units extending from both ends of the fourth wiring unit, and fourth inlet units extending from one end of the fourth connection unit and electrically connected to the external power source.

8. The flat panel display apparatus of claim 7, wherein the first inlet unit and the second inlet unit are adjacent to each other and are spaced apart from each other by a predetermined interval, the second inlet unit and the third inlet unit are adjacent to each other and are spaced apart from each other by a predetermined interval, the third inlet unit and the fourth inlet unit are adjacent to each other and are spaced apart from each other by a predetermined interval, and the fourth inlet unit and the first inlet unit are adjacent to each other and are spaced apart from each other by a predetermined interval.

9. The flat panel display apparatus of claim 6, wherein the first inlet unit, the second inlet unit, the third inlet unit, and the fourth inlet unit are each exposed at one side of the substrate, and are each connected to the external power source.

10. The flat panel display apparatus of claim 1, wherein the sealing member comprises frit.

11. The flat panel display apparatus of claim 1, wherein each of the wiring groups comprises a single wiring member.

12. The flat panel display apparatus of claim 1, wherein the display unit comprises one of an organic light-emitting device and a liquid crystal display device.

13. A method of manufacturing a flat panel display apparatus, the method comprising the steps of:
preparing a substrate on which a display unit is disposed;
disposing a sealing substrate to face the display unit;
forming a sealing member between the substrate and the sealing substrate and surrounding the display unit;
forming a plurality of wiring groups comprising areas overlapping the sealing member between the substrate and the sealing substrate; and
melting and hardening the sealing member by using heat generated by the wiring groups as a result of applying an external power source to the plurality of wiring groups;
wherein wiring groups which are adjacent to each other are spaced apart from each other by a predetermined interval and are electrically insulated from each other.

14. The method of claim 13, wherein the step of melting and hardening the sealing member comprises selecting the wiring groups which are not adjacent to each other and applying the external power source to the selected wiring groups.

15. The method of claim 13, wherein the wiring groups are each disposed so as to correspond to a side of the display unit.

16. The method of claim 15, wherein the step of melting and hardening the sealing member comprises selecting wiring groups which face each other and applying the external power source to the selected wiring groups.

17. The method of claim 15, wherein the wiring groups include a first wiring group, a second wiring group, a third wiring group, and a fourth wiring group which are each spaced apart from four sides of the display unit.

18. The method of claim 17, wherein the first wiring group comprises a first wiring unit overlapping the sealing member, first connection units extending from both ends of the first wiring unit, and first inlet units extending from one end of the first connection unit and electrically connected to the external power source;
wherein the second wiring group comprises a second wiring unit overlapping the sealing member, second connection units extending from both ends of the second wiring unit, and second inlet units extending from one end of the second connection unit and electrically connected to the external power source;
wherein the third wiring group comprises a third wiring unit overlapping the sealing member, third connection units extending from both ends of the third wiring unit, and third inlet units extending from one end of the third connection unit and electrically connected to the external power source; and
wherein the fourth wiring group comprises a fourth wiring unit overlapping the sealing member, fourth connection units extending from both ends of the fourth wiring unit, and fourth inlet units extending from one end of the fourth connection unit and electrically connected to the external power source.

19. The method of claim 18, wherein the step of melting and hardening the sealing member comprises selecting the first inlet unit, selecting the second inlet unit, selecting the third inlet unit, selecting the fourth inlet unit, and applying the external power source to the selected inlet units.

20. The method of claim 18, wherein the step of melting and hardening the sealing member comprises selecting the first inlet unit and the third inlet unit which face each other, applying the external power source to each of the selected first inlet unit and the selected third inlet unit, selecting the second inlet unit and the fourth inlet unit which face each other, and applying the external power source to each of the selected second inlet unit and the selected fourth inlet unit.

21. The method of claim 13, wherein the sealing member comprises frit.

22. The method of claim 13, wherein the wiring groups each comprise a single wiring member.

23. The method of claim 13, wherein the display unit comprises one of an organic light-emitting device and a liquid crystal display device.
